(19) United States
(12) Patent Application Publication
(10) Pub. No.: US 2015/0345184 A1
(43) Pub. Date: Dec. 3, 2015

(54) COMPONENT CARRIER FOR ELECTRICAL/ELECTRONIC COMPONENTS

(71) Applicant: KIEKERT AKTIENGESELLSCHAFT, Heiligenhaus, North Rhine-Westphalia (DE)

(72) Inventors: Asmus Koch, Koln, North Rhine-Westphalia (DE); Inga Heinzen, Krefeld, North Rhine-Westphalia (DE); Jan Fassel, CZ-Nejdek, Karlovy Vary (CZ); Jan Suk, CZ-Cechtice, Central Bohemian (CZ)

(21) Appl. No.: 14/655,800

(22) PCT Filed: Dec. 23, 2013
(86) PCT No.: PCT/DE2013/000823

§ 371 Date: Jul. 20, 2015

(30) Foreign Application Priority Data
Dec. 27, 2012 (DE) 20 2012 105 072.2

(51) Int. Cl. E05B 81/54; H05K 7/02

(52) U.S. Cl. CPC E05B 81/54; H05K 7/02

(57) ABSTRACT

Component carrier for electrical/electronic components, for example for the combination with a lock housing or as a component of a lock housing of a motor vehicle door lock, comprising a carrier element and a conductor track structure of individual metallic conductor tracks, which can be connected to the carrier element, wherein at least one conductor track of the conductor track structure comprises in some areas a multi-layer structure and, in particular, a double-layer structure.

### CROSS-REFERENCE TO RELATED APPLICATIONS

This application is the U.S. national stage application of International Patent Application No. PCT/DE2013/000823, filed Dec. 23, 2013, which claims priority of German Application No. 20 2012 105 072.2, filed Dec. 27, 2012, which are both hereby incorporated by reference.

### BACKGROUND

The invention relates to a component carrier for electrical/electronic components, for example for the combination with a latch housing or as a component of a latch housing of a motor vehicle door latch, comprising a carrier element and a strip conductor structure consisting of individual metallic strip conductors, which can be connected to the carrier element.

The component carrier with the aforementioned design, as disclosed in DE 10 2005 049 975 C5 is a latch housing of a motor vehicle door latch, containing at least one base element. The strip conductor structure is made from tinplate, consisting of cold-rolled sheet steel with a thickness of up to 0.5 mm. Also, a white shimmering tin coating of 5 μm is electrolytically applied. In this manner, a cost effective and sturdy design of a component carrier is provided.

Similar component carriers are disclosed in DE 101 39 356 A1 or also in DE 20 2010 009 708 U1.

As usual, the component carrier serves to accommodate electrical and/or electronic components on its carrier element and to connect the components to each other or to a remote control unit with the aid of a strip conductor structure. Once the electrical or electronic components have been fitted, the entire component carrier is usually encased in a casting compound in order to protect it against environmental influences. The strip conductor structure is generally a leadframe combining the different strip conductors and allowing their joint production. Together with the carrier element or the electrical/electronic components, the strip conductor structure is, once completed, mostly or entirely encased in casting compound. This procedure has generally proven to be successful.

For reasons of cost, prior art embodiments or practical applications generally have the aim of keeping the material thickness of the used strip conductor structure as thin as possible. The generic teaching disclosed in DE 10 2005 049 975 C5 uses at this point tinplate with a thickness of only up to 0.5 mm. The trend of saving material and using thinner and thinner material thicknesses results, however, in increasing installation problems. Especially when connecting motors or other larger and weighty components and electrical and electronic components to the strip conductor structure the problem occurs that angled lugs of the strip conductor structure can be inadvertently bent. This can even occur during operation as a result of the unavoidable movements of the motor. Consequently, contact problems can occur in practical application, which become particularly problematic after a certain operating time and are difficult to remedy. The invention aims to provide a solution for this.

### SUMMARY

The invention is based on the technical problem of, further developing said component carrier in such a way that current and future contact problems basically no longer occur and that permanent correct functioning is guaranteed.

In order to solve this technical problem, a generic component carrier according to the invention is characterized by at least one strip conductor of the strip conductor structure comprising in some areas a multi-layer structure and in particular a double-layer structure. According to an advantageous embodiment, the at least one strip conductor contains a multi-layer structure and in particular a double-layer structure in the area of the lug.

The respective lug is generally angled and, in particular, perpendicular to the main plane of the strip conductor structure. As a result, the lug typically functions as a plug or plug contact protruding from the main plane of the strip conductor structure for receiving a connector. It is also possible to solder the lug to a contact of the respective electric/electronic component. Generally the respective lug is used for connecting the respective electric motor. In the invention, only this lug of the strip conductor structure used for providing the electric contact of the respective electric motor is designed as a multi-layer structure and, in particular, a double-layer structure.

In this way, the invention counteracts the fact that in particular the lugs used as contacts for electric motors, are subjected to the specific mechanical stressing described with reference to prior art embodiments. In order to prevent, in this context, such mechanical stressing and, in particular, bending, snapping or even breaking of the lugs, the respective lug is, according to the invention, designed as a multi-layer structure and, in particular, a double-layer structure.

The invention also takes into account that according to the invention the strip conductor structure generally has a continuous material thickness of less than 0.5 mm and in particular 0.4 mm and less. As the lug has a multi-layer structure and, in particular, a double-layer structure, at least double the material thickness is provided, which generally is or can be 0.8 mm and even 1 mm. Due to the greater material thickness in the area of the lug used for the connection of the electric motor, all mechanical stressing during assembly as well as during the subsequent operation are absorbed and managed. Compared to previous component carriers reliability is thus considerably increased.

In order to achieve this in detail, the multi-layer structure or double-layer structure is typically designed as a fold with a folded cover trimmed at the folding edge. This means that during the production of the double-layer structure as a fold, first the respective strip conductor is folded at the folding edge, mostly taking into consideration an approximately rectangular bending angle. This folded section is then provided with a cover, i.e. the folded section is folded back on itself using a bending angle of approx. 180° or is folded in the manner of such a formed cover against the folded section. This results in said fold.

As a result, the invention provides a rounded front edge in the area of the multi-layer structure or double-layer structure, preventing or excluding any injuries when pushing a connector onto this double layer or the respectively designed lug.

Apart from this multi-layer structure or double-layer structure in the area of the lug of the respective strip conductor it has also proven to be advantageous for the respective multi-layer structure or double-layer structure to contain at least one two-sided connecting web. Actually the multi-layer structure and, in particular, the double-layer structure are equipped with a two-sided connecting web. The respective lug for connecting the electric motor consequently has a Ω-like cross section, in which the two Ω-legs abut and in which the Ω-feet define the respective connecting webs on both sides.

As generally, these connecting webs are provided on the component carrier, for instance as a pre-fixed or pre-molded web, the respectively equipped lug is particularly stable and reliably prevents snapping, bending or breaking, etc.

This also applies where the strip conductor structure as a whole is made of brass, i.e. a relatively soft and cold-forming metal.

This requirement is all the more fulfilled where, as an alternative, tinplate or similar with, where applicable, a tin coating for corrosion protection, is used for the production of the strip conductor structure. Generally, brass is, however, used by the invention.

It has proven to be advantageous that despite the entire strip conductor structure being made of brass with a material thickness of less than 0.5 mm and, in particular, of less than 0.4 mm and thinner, the required stability and sturdiness is achieved at the critical points. These critical points are generally the lugs for connecting the (respective) electric motor. According to the invention, these lugs of the strip conductor structure are designed as a multi-layer structure and, in particular, a double-layer structure, as already described in detail. As a result, the invention combines maximum material savings with the required reliability over the entire service life. Previously this was regarded as impossible. These are thus the particular advantages of the invention.

Below, the invention is explained in detail with reference to a drawing showing only one embodiment, in which:

### BRIEF DESCRIPTION OF THE DRAWINGS

FIG. 1 shows a perspective view of a component carrier of the invention for electrical/electronic components in form of a latch housing of a motor vehicle door latch and

FIG. 2 shows details of the strip conductor structure of FIG. 1, also as a perspective view.

### DETAILED DESCRIPTION OF THE DRAWINGS

The figures show a component carrier for electrical/electronic components 1, 2, 3. In the example, the component carrier is part of a latch housing 4 of a motor vehicle door latch, not shown, acting as a carrier element 4. Generally, the component carrier can, however also be provided as a separate entity arranged or positioned inside the latch housing 4. This is, however, not shown. This means that in the embodiment, the carrier element 4 and the latch housing 4 are synonymous or the component carrier represents a part of the latch housing 4 of the respective motor vehicle door latch, with the latch housing 4 as a whole or in parts acting as a carrier element 4 of the component carrier.

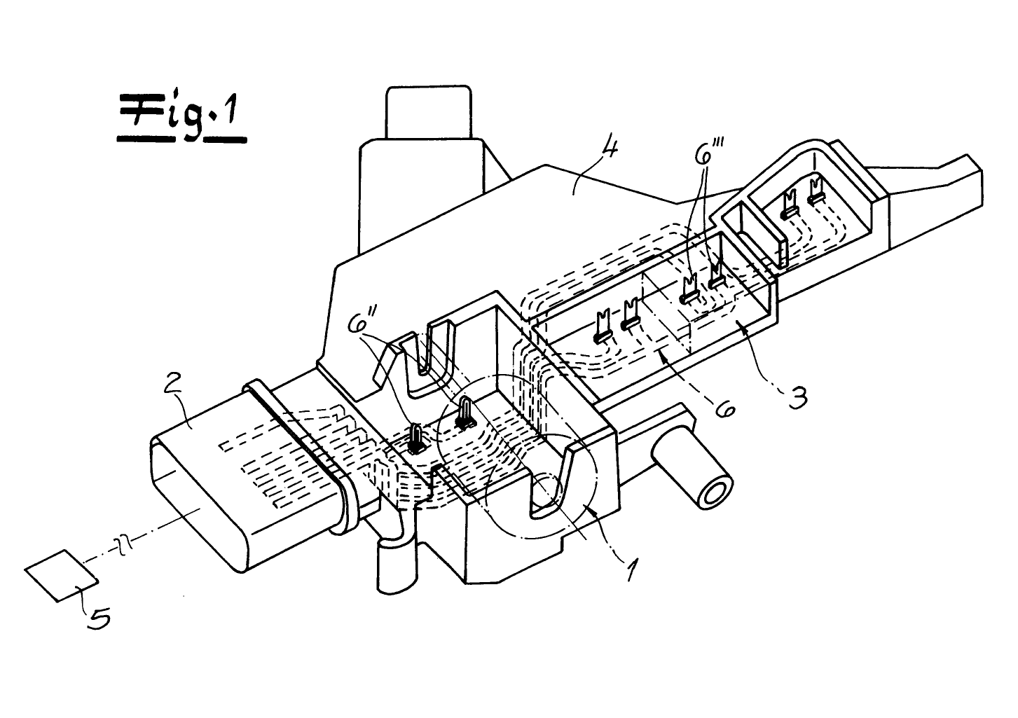

The electrical/electronic components 1, 2, 3 consist of an electric motor 1, only indicated, positioned in a respective motor seat or motor trough. FIG. 1 shows parts of the socket 2 provided for a connector, not shown, with the aid of which the electrical/electronic components 1, 2, 3 are electrically connected to a remote control unit 5, which is only indicated.

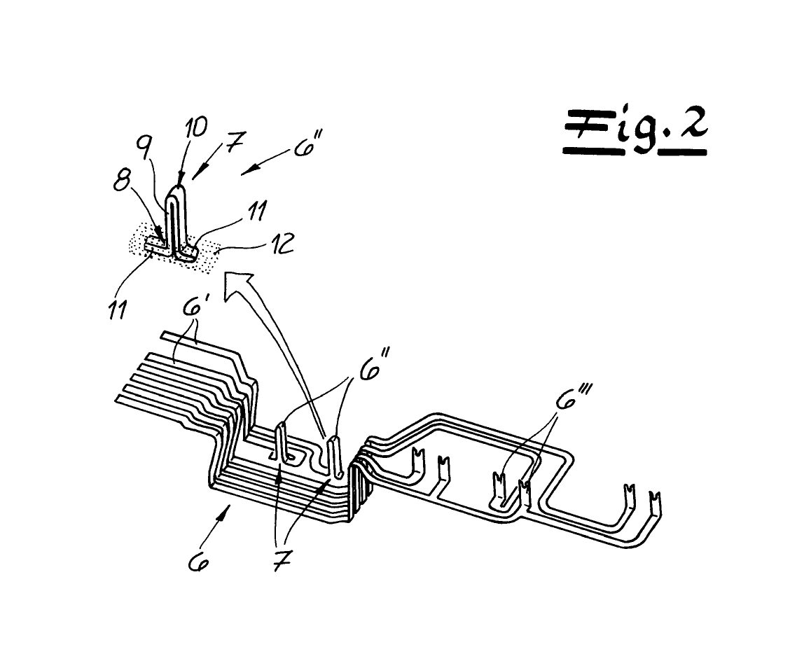

The electrical or electronic component 3 is a micro switch 3, shown in FIG. 1 as an example, which senses, for instance, individual functional positions of mechanical elements of the motor vehicle door latch. The electrical/electronic components 1, 2, 3 explained above and provided only as an example and which are not shown and described in full, are supported or accommodated on the latch housing 4, operating as a carrier element 4. A strip conductor structure 6 shown in detail in FIG. 2 can be connected to the carrier element 4.

The strip conductor structure 6 contains individual metallic strip conductors 6′ as well as also indicated lugs 6″ and 6′″ as respective components of the associated strip conductor 6′. The lugs 6″ allow connection of the electric motor 1. In contrast, the lugs 6′″ are provided for connecting the micro switch 2.

FIG. 2 and the enlarged extract in FIG. 2 show that according to the invention at least two strip conductors 6′ of the strip conductor structure 6 contain a multi-layer structure and, in particular, a double-layer structure 7. The respective lug 6″ or 6′″ is arranged at an angle and, in particular, perpendicular to a main plane of the strip conductor structure 6. The main plane of the strip conductor structure 6 is provided by the mainly horizontal strip conductors 6′. In contrast, the lugs 6″ and 6′″ extend at an angle and, in particular, perpendicular to said main plane.

The enlarged view in FIG. 2 shows that the multi-layer structure or double-layer structure 7 is designed as a fold. The fold is formed by the respective strip conductor 6′ being first folded along a fold edge 8 and mainly in a rectangular manner. In this way, a folded edge 9 is defined. The folded edge 9 only serves as a starting point for a cover 10, as the folded edge 9 is bent back on itself, taking into consideration a bending angle of 180° and is folded against the folded edge 9. In this way the said cover 10 is defined and described.

As a result, the lug 6″ contains a Ω-like cross section, as clearly shown in the enlarged view of FIG. 2. Also the respective connecting webs 11 on both sides of the cover 10 are apparent. During production of the component carrier, these connecting webs 11 are typically embedded in a material 12 covering the carrier element 4, said material generally being an adhesive or sealing material 12. The adhesive or sealing material 12 is applied onto the carrier element 4 during a so-called initial molding in order to secure the strip conductor structure 6 placed on or inserted in the carrier element.

As a result of the adhesive or sealing material 12 and the connecting webs 11 anchored therein, as well as the cover 10 or the thus produced double-layer structure or multi-layer structure 7 in the area of the lug 6″, the electric motor 1 can be connected correctly and without damage, i.e. without bending or breaking the respective lug 6″. This also ensures a permanent connection.

The strip conductor structure 6 has a continuous material thickness of typically less than 0.5 mm and, in particular, of 0.4 mm and less. This results in considerable material savings compared to prior art strip conductors 6. In addition, the double-layer structure or multi-layer structure 7 in the area of the lug 6″ for the electric motor 1 provides at least double the material thickness of approx. 0.8 mm and more at this point. This provides the respective lug 6″ with the required stability and rigidity in order to prevent the aforementioned damage.

The strip conductor structure 6 is generally made from brass. In principle, the strip conductor structure 6 can, however, also be made from tinplate. The strip conductor structure 6 is generally a stamped part which during the stamping or subsequently is provided with the described multi-layer structure or double-layer structure 7 at least in the area of the lug 6″ used for connecting the electric motor 1.

1. Component carrier for electrical/electronic components, for example for a combination with a latch housing or as a component of a latch housing of a motor vehicle door latch, comprising a carrier element and a strip conductor structure of individual metallic strip conductors which can be connected to the carrier element, characterized in that at least one strip conductor of the strip conductor structure comprises in some areas a multi-layer structure and, in particular, a double-layer structure.

2. Component carrier according to claim 1, characterized in that in an area of a lug, the strip conductor comprises the multi-layer structure and, in particular, the double-layer structure.

3. Component carrier according to claim 2, characterized in that in the lug is arranged at an angle and, in particular, perpendicularly to a main plane of the strip conductor structure.

4. Component carrier according to claim 1, characterized in that the multi-layer structure and, in particular, the double-layer structure is formed as a fold with a cover trimmed and folded at a folding edge.

5. Component carrier according to claim 1, characterized in that the multi-layer structure and, in particular, the double-layer structure is formed as a doubling or double-layer structure with a connecting web on either side.

6. Component carrier according to claim 5, characterized in that the multi-layer structure and, in particular, the double-layer structure contains a Ω-like cross section.

7. Component carrier according to claim 1, characterized in that the strip conductor structure has a continuous material thickness of less than 0.5 mm and in particular of 0.4 mm and less.

8. Component carrier according to claim 1, characterized in that a lug of the strip conductor structure only provided as a connection for the electric motor is formed as a multi-layer structure and, in particular, a double-layer structure.

9. Component carrier according to claim 1, characterized in that the strip conductor structure is made from brass, tinplate or similar.

10. Component carrier according to claim 1, characterized in that the strip conductor structure is a stamped component.

11. Component carrier according to claim 3, characterized in that the multi-layer structure and, in particular, the double-layer structure is formed as a fold with a cover trimmed and folded at a folding edge.

12. Component carrier according to claim 11, characterized in that the multi-layer structure and, in particular, the double-layer structure is formed as a doubling or double-layer structure with a connecting web on either side.

13. Component carrier according to claim 12, characterized in that the multi-layer structure and, in particular, the double-layer structure contains a Ω-like cross section.

14. Component carrier according to claim 13, characterized in that the strip conductor structure has a continuous material thickness of less than 0.5 mm and in particular of 0.4 mm and less.

15. Component carrier according to claim 14, characterized in that the lug of the strip conductor structure only provided as a connection for the electric motor is formed as a multi-layer structure and, in particular, a double-layer structure.

16. Component carrier according to claim 15, characterized in that the strip conductor structure is made from brass, tinplate or similar.

17. Component carrier according to claim 16, characterized in that the strip conductor structure is a stamped component.
